(19) United States
(12) Patent Application Publication
(10) Pub. No.: US 2002/0090758 A1
(43) Pub. Date: Jul. 11, 2002

(54) Method and resulting device for manufacturing for double gated transistors

(75) Inventors: Francois J. Henley, Los Gatos, CA (US); Nathan Cheung, Albany, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Silicon Genesis Corporation, Campbell, CA

(21) Appl. No.: 09/956,486

(22) Filed: Sep. 18, 2001

Related U.S. Application Data
(60) Provisional application No. 60/233,806, filed on Sep. 19, 2000.

(51) Int. Cl. H01L 21/44

(52) U.S. Cl. 438/110

(57) ABSTRACT

A process for forming an integrated circuit device structure. The process includes forming a first gate layer on a thickness of material on a donor substrate. The donor substrate has a cleave region underlying the gate layer. The process also includes joining the donor substrate to a handle substrate where the gate layer face the handle substrate; and separating the thickness of material at the cleave region from the donor substrate to define a handle substrate comprising the gate layer and an overlying thickness of material. The process forms a plurality of second gate structures on the thickness of material, where at least one of the first gate structures facing one of the second gate structures forming a channel region therebetween.

### CROSS REFERENCE TO RELATED APPLICATIONS

This application is a continuation in part of and claims priority to Provisional Patent Application Ser. No. 60/233,806 filed Sep. 19, 2000, which is hereby incorporated by reference in its entirety for all purposes.

### BACKGROUND OF THE INVENTION

The present invention relates to the manufacture of integrated circuit devices. More particularly, the invention provides a technique including a method and device for cleaving a film of material on substrate in the fabrication of a double gate structure for MOS semiconductor integrated circuits. Merely by way of example, the invention can be applied to the manufacture of MOS integrated circuit devices using semiconductor technology, but it will be recognized that the invention has a much wider range of applicability.

Techniques for manufacturing semiconductor devices have improved through the years. In the early days, Robert N. Noyce invented what we understand as the “integrated circuit,” which is described in U.S. Pat. No. 2,981,877, titled Semiconductor Device-And-Lead Structure, filed Jul. 30, 1959, and issued Apr. 25, 1961 (herein the “Noyce patent”). The Noyce patent generally describes a technique for interconnecting two contact regions for manufacturing an integrated circuit. The Noyce patent was one of the many techniques which has been developed for making semiconductor devices more integrated and closely packed such that more and more transistors can be designed in a given area.

Another technique that has been developed to make transistors more compact in a given area is described in U.S. Pat. No. 4,256,514, assigned to International Business Machines Corporation, and in the name of Hans B. Pogge (herein the “Pogge” patent). The Pogge patent generally describes a way of manufacturing a narrow dimensioned region on a silicon body. Such narrowed dimensioned region, commonly called a side wall spacer, is generally formed on sides of gate regions on MOS transistors. Gate regions with spacers are often used in highly integrated MOS transistor devices. Although each of these techniques has been successful for the manufacture of conventional integrated circuit devices, industry desires other ways of manufacturing semiconductor devices in even a more integrated and denser manner.

From the above, it is seen that a technique for manufacturing highly integrated circuit devices is often desirable.

### SUMMARY OF THE INVENTION

According to the present invention, an improved technique for manufacturing integrated circuit device structures is provided. More particularly, the invention provides a technique including a method and device for cleaving a substrate in the fabrication for a double gate structure for semiconductor integrated circuits. Merely by way of example, the invention can be applied to the manufacture of MOS integrated circuit devices using semiconductor technology, but it will be recognized that the invention has a much wider range of applicability.

In a specific embodiment, the invention provides a process for forming an integrated circuit device structure. The process includes forming a plurality of first gate structures on a thickness of material on a donor substrate (e.g., silicon wafer). The donor substrate has a cleave region underlying the plurality of gate structures. The process also includes joining the donor substrate to a handle substrate where the plurality of gate structures face the handle substrate; and separating (e.g., controlled cleaving process) the thickness of material at the cleave region from the donor substrate to define a handle substrate comprising the plurality of gate structures and an overlying thickness of material. The process forms a plurality of second gate structures on the thickness of material, where at least one of the first gate structures facing one of the second gate structures forming a channel region therebetween. One of ordinary skill in the art would recognize many other variations, modifications, and alternatives.

In an alternative specific embodiment, the invention provides a multi-gate MOS transistor structure. The transistor has a handle substrate and a gate region defined overlying the handle substrate. A first gate dielectric region is defined overlying the gate region. A cleaved region forms a channel region defined overlying the first gate dielectric region. The channel region is also defined overlying the first gate region. Preferably, the cleaved region has a thickness of less than 1000 A and having a uniformity of 1 to 10%. A second gate dielectric region is defined overlying the channel region. A second gate region is defined overlying the second gate dielectric region and is also defined overlying the channel region. The second gate opposes the first gate and has the channel region defined between the first gate and the second gate. In some embodiments the transistor the gates are defined in a self-aligned method as well. For this, the lower gate material, gate dielectric material, and a semiconducting material are first formed. Such materials can be formed without patterning and formed continuously overlying each other to form a sandwiched structure. The upper oxide and gate are then formed using planar processing techniques such as oxidation followed by gate material deposition. The structure, including lower gate structure (e.g., gate, gate dielectric), semiconducting material (e.g., channel), and upper gate (e.g., gate, gate dielectric), is then patterned. Here, photolithography and etching techniques would form and define both the upper and lower gate, thereby etching through many or all the layers together in a self aligned process.

In an alternative specific embodiment, the invention provides another method for forming an integrated circuit device structure. The method includes forming a first gate layer on a thickness of material on a donor substrate, which has a cleave region underlying the first gate layer. The first gate layer has a substantially planar upper surface. The method joins the donor substrate to a handle substrate where the first gate layer including the planar upper surface face the handle substrate. A step of separating the thickness of material at the cleave region from the donor substrate to define a handle substrate comprising the first gate layer and the overlying thickness of material is included. The method then forms a second gate layer overlying the thickness of material to define a sandwiched structure including the first gate layer, the detached thickness of material, and second gate layer. The method patterns the sandwiched structure to define a first gate structure from the first gate layer defined opposite of a second gate structure from the second gate layer using at least an etching process where upon a channel region is defined from the detached and patterned thickness of material defined between the first gate structure and the second gate structure. Preferably, the step of patterning provides a self aligned process that aligns the first gate structure with the second gate structure.

Numerous benefits are achieved by way of the present invention over conventional techniques. For example, the present invention can be implemented using conventional semiconductor technologies. Additionally, the present invention can be used for the manufacture of integrated circuit devices having channel widths of less than 100 or 50-70 nm. Other benefits are an increase in transconductance (transistor current carrying performance for a specific gate length and width of 2-2.5X, and the reduction or effective elimination of the so called “short-channel effect” that occurs in very short-channel single-MOS gate devices around 0.1 um (100 nm) or less and reduces the transistor performance. Depending upon the embodiment, one or more of these benefits may exist. These and other benefits are described throughout the present specification and more particularly below.

The present invention achieves these benefits and others in the context of known process technology. However, a further understanding of the nature and advantages of the present invention may be realized by reference to the latter portions of the specification and attached drawings.

### BRIEF DESCRIPTION OF THE DRAWINGS

FIGS. 1-10 are simplified diagrams illustrating a method and resulting structure for a double gate integrated circuit according to embodiments of the present invention

### DESCRIPTION OF THE SPECIFIC EMBODIMENTS

According to the present invention, an improved technique for manufacturing integrated circuit device structures is provided. More particularly, the invention provides a technique including a method and device for cleaving a film of material including gate regions of an MOS transistor structure from a substrate for the fabrication for a double gate structure of semiconductor integrated circuits. Merely by way of example, the invention can be applied to the manufacture of MOS integrated circuit devices using semiconductor technology, but it will be recognized that the invention has a much wider range of applicability. The invention will be better understood by reference to the Figs. and the descriptions below.

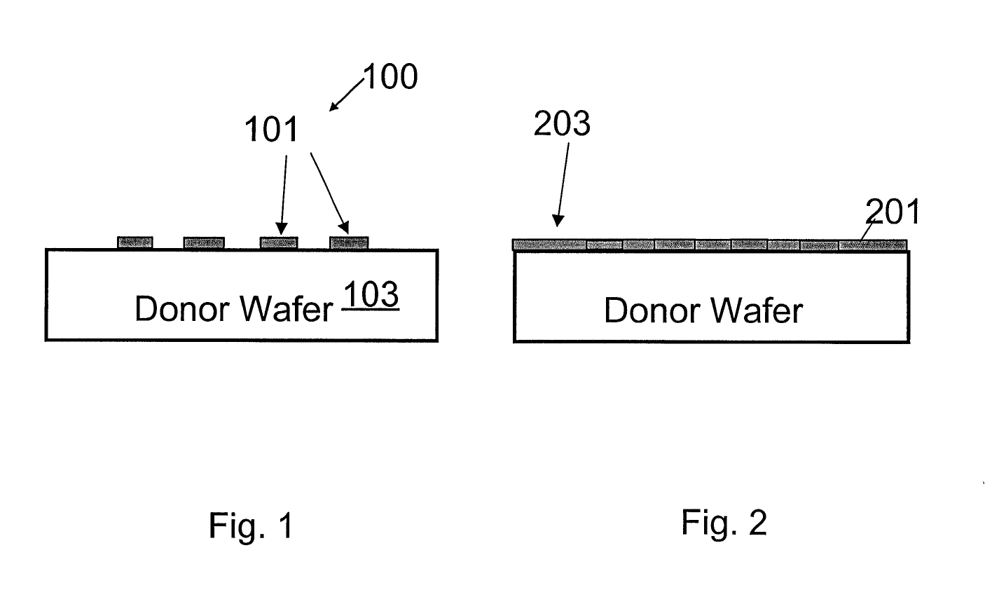

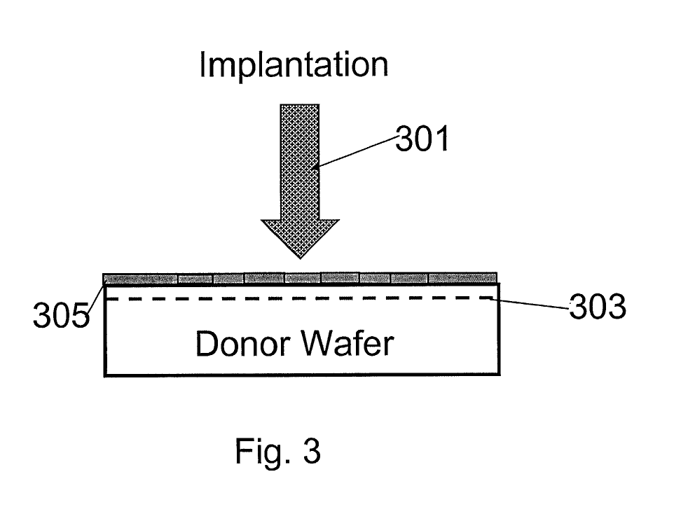

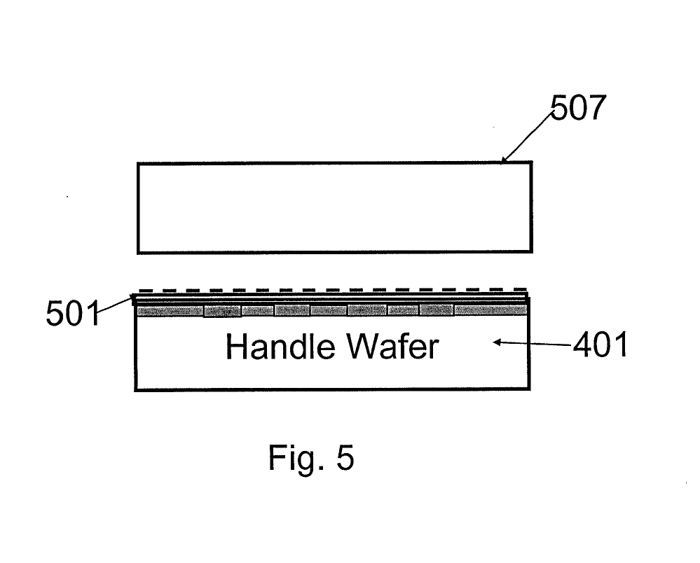

FIGS. 1-9 are simplified diagrams illustrating a method for fabricating a double gate integrated circuit structure according to an embodiment of the present invention. These diagrams are merely illustrations and should not unduly limit the scope of the claims herein. One of ordinary skill in the art would recognize many other variations, modifications, and alternatives. As shown, the method begins by providing a donor wafer 103, which forms substrate structure 100. The substrate structure includes donor wafer 103 having a plurality of gate regions 101. The donor wafer is often a bulk wafer such as a bulk silicon wafer, but can also be a multilayered structure or the like. Each of the gate regions is formed using a deposition of polysilicon, which is later patterned to form such regions. The polysilicon is often doped with an impurity. The impurity is often introduced into the polysilicon layer using implantation, diffusion, in-situ doping, any combination of these, and the like. Preferably, the polysilicon layer is deposited in an amorphous state using in-situ doping techniques. Such amorphous polysilicon layer is later recrystallized.

Referring to FIG. 2, the method forms a layer of dielectric material overlying the substrate structure 100. In a specific embodiment, the method forms a dielectric layer 201 overlying the surface of the substrate structure. The dielectric layer is planarized using chemical mechanical polishing or the like. Alternatively, the dielectric layer can be a spin on glass or other form of material, which fills in the regions or gaps between the gate regions. The substrate structure including gate and dielectric regions has a substantially planar surface in a preferred embodiment. The dielectric layer serves as insulation between each of the gate regions.

Next, the method introduces 301 particles through the surface of the substrate to a selected region 303 or depth. Alternatively, particles can be diffused to the selected depth. In a specific embodiment, selected energetic particles implant through the top surface of the substrate structure to the selected depth, which defines a thickness 305 of a material region including the gate regions, which is later cleaved, i.e., cleaved layer. A variety of techniques can be used to implant the energetic particles into the silicon wafer. These techniques include ion implantation using, for example, beam line ion implantation equipment manufactured from companies such as Applied Materials, Eaton Corporation, Varian, and others. Alternatively, implantation occurs using a plasma immersion ion implantation (“PIII”) technique. Examples of plasma immersion implantation techniques are described in “Recent Applications of Plasma Immersion Ion Implantation,” Paul K. Chu, Chung Chan, and Nathan W. Cheung, SEMICONDUCTOR INTERNATIONAL, pp. 165-172, June 1996, and “Plasma Immersion Ion Implantation—A Fledgling Technique for Semiconductor Processing,”, P. K. Chu, S. Qin, C. Chan, N. W. Cheung, and L. A. Larson, MATERIAL SCIENCE AND ENGINEERING REPORTS, A Review Journal, pp. 207-280, Volume R17, Nos. 6-7, (Nov. 30, 1996), which are both hereby incorporated by reference for all purposes. Furthermore, implantation can occur using ion shower. Of course, techniques used depend upon the application.

Depending upon the application, smaller mass particles are generally selected to reduce a possibility of damage to the thickness of the material region 305, which includes gate regions. That is, smaller mass particles easily travel through the substrate material including gate regions to the selected depth without substantially damaging the material region that the particles traverse through. For example, the smaller mass particles (or energetic particles) can be almost any charged (e.g., positive or negative) and/or neutral atoms or molecules, or electrons, or the like. In a specific embodiment, the particles can be neutral and/or charged particles including ions such as ions of hydrogen and its isotopes (i.e., deuterium), and the like. The particles can also be derived from compounds such as gases, e.g., hydrogen gas, water vapor, methane, and hydrogen compounds, and other light atomic mass particles. Alternatively, the particles can be any combination of the above particles, and/or ions and/or molecular species and/or atomic species. The particles generally have sufficient kinetic energy to penetrate through the surface to the selected depth underneath the surface.

Using hydrogen as the implanted species into the silicon wafer as an example, the implantation process is performed using a specific set of conditions. Implantation dose ranges from about 10¹⁵ to about 10¹⁸ atoms/cm², and preferably the dose is greater than about 10¹⁵ atoms/cm². Implantation energy ranges from about 1 KeV to about 1 MeV , and is generally about 50 KeV. Implantation temperature ranges from about −200 to about 600 Degrees C., and is preferably less than about 400 Degrees C. to prevent a possibility of a substantial quantity of hydrogen ions from diffusing out of the implanted silicon wafer and annealing the implanted damage and stress. The hydrogen ions can be selectively introduced into the silicon wafer to the selected depth at an accuracy of about +/−0.03 to +/−0.05 microns. Of course, the type of ion used and process conditions depend upon the application.

In an alternative embodiment, chemical and or other stress can be introduced by adding heavier particles to the selected depth of the material region. Here, the heavier particles include one or any combination of silicon, oxygen, germanium, carbon, nitrogen, or any other suitable heavier particle that can add stress and enhance cleaving of the material region. These heavier particles can be implanted through the material region or can be diffused or the like. In a specific embodiment, a dose requirement for these heavier particles would generally be less than that of lighter particles. A combination of heavier and lighter particles can also be used in other embodiments. Depending upon the application, many other ways of introducing stress can also be used.

Effectively, the implanted particles add stress or reduce fracture energy along a region parallel to the top surface of the substrate at the selected depth. The energies depend, in part, upon the implantation species and conditions. These particles reduce a fracture energy level of the substrate at the selected depth. This allows for a controlled cleave along the implanted plane at the selected depth. Implantation can occur under conditions such that the energy state of substrate at all internal locations is insufficient to initiate a non-reversible fracture (i.e., separation or cleaving) in the substrate material. It should be noted, however, that implantation may under selected conditions cause a certain amount of defects (e.g., micro-defects) in the substrate that can be repaired by subsequent heat treatment, e.g., thermal annealing or rapid thermal annealing.

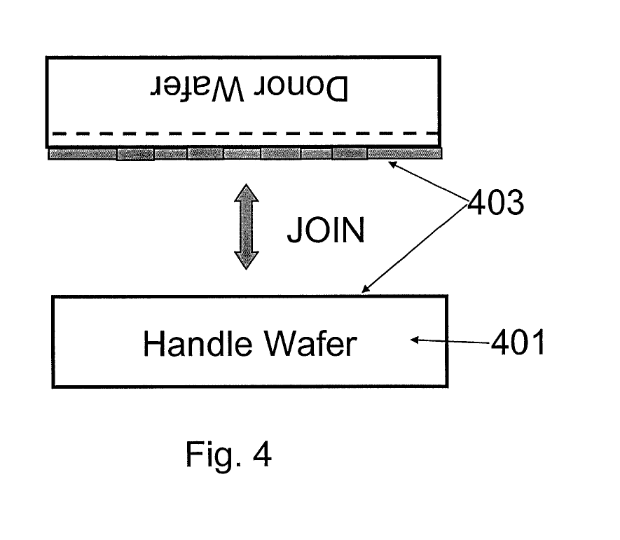

Referring to FIG. 4, the upper implanted surface of the donor substrate structure is bonded to a handle wafer 401. The handle wafer can be made of any suitable material such as bulk silicon, multilayered, and the like. The implanted substrate or stressed substrate bonds through an interface 403, which can be almost any type of adhesive layer. The adhesive layer can include silicon dioxide, for example, as well as many other suitable materials. In a specific embodiment, the adhesive layer is often a high quality dielectric material such as thermal oxide. Such thermal oxide acts as a gate dielectric layer for the gate region. The gate dielectric layer often has a thickness of about 10-50 A and less for applications where the channel region has a length of 25-100 nm. Of course, the selected thickness of the dielectric layer depends upon certain design rules and other factors. This bonded multilayered structure is then subjected to the cleaving process, which is described below.

Here, donor substrate structure 507 is removed from the thickness of material 305. The thickness of material includes a portion of the donor substrate 501, which can be single crystal silicon or the like. In a specific embodiment, the substrate wafer undergoes a step of selective energy placement or positioning or targeting which provides a controlled cleaving action of the material region 305 at the selected depth. In preferred embodiments, selected energy placement occurs near an edge or corner region of the selected depth of the substrate structure. The impulse (or impulses) is provided using energy sources. Examples of sources include, among others, a chemical source, a mechanical source, an electrical source, and a thermal sink or source. The chemical source can include a variety such as particles, fluids, gases, or liquids. These chemical sources can also include chemical reaction to increase stress in the material region. The chemical source is introduced as flood, time-varying, spatially varying, or continuous. In other embodiments, a mechanical source is derived from rotational, translational, compressional, expansional, or ultrasonic energies. The mechanical source can be introduced as flood, time-varying, spatially varying, or continuous. In further embodiments, the electrical source is selected from an applied voltage or an applied electromagnetic field, which is introduced as flood, time-varying, spatially varying, or continuous. In still further embodiments, the thermal source or sink is selected from radiation, convection, or conduction. This thermal source can be selected from, among others, a photon beam, a fluid source, a liquid source, a gas source, an electro/magnetic field, an electron beam, a thermo-electric heating, a furnace, and the like. The thermal sink can be selected from a fluid source, a liquid source, a gas source, a cryogenic fluid, a super-cooled liquid, a thermoelectric cooling means, an electro/magnetic field, and others. Similar to the previous embodiments, the thermal source is applied as flood, time-varying, spatially varying, or continuous. Still further, any of the above embodiments can be combined or even separated, depending upon the application. Of course, the type of source used depends upon the application. Preferably, the cleaving is initiated using a mechanical member applied to a region near or on the stressed region to initiate the cleaving action. As merely examples, such methods for cleaving the substrate structure may be described in U.S. Pat. Nos. 6,291,313, 6,033,974, 6,284,631, in the names of Francois J. Henley and Nathan Cheung, commonly assigned, and hereby incorporated by reference for all purposes.

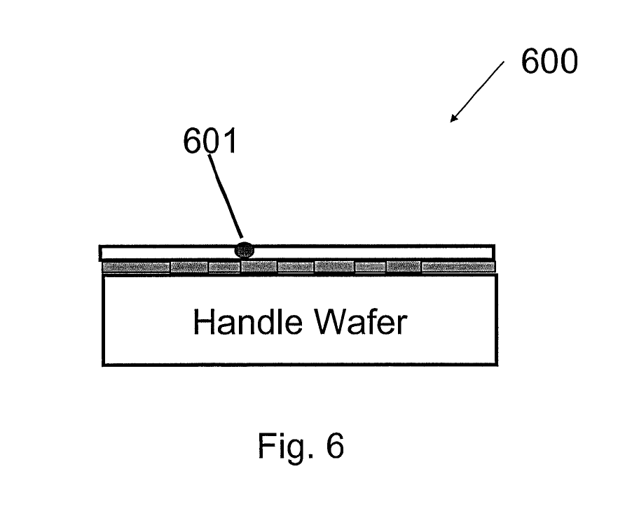

Next, the cleaved structure is represented by the simplified diagram of FIG. 6. As shown, a device layer 601 is exposed overlying the gate and dielectric regions. The device layer can be used as a channel layer according to a specific embodiment. Preferably, the device layer is high quality single crystal silicon in the [100] orientation. The device layer can also be implanted or doped using an impurity of selected characteristics. For example, the impurity can be boron as well as phosphorous or other suitable impurities. Of course, one of ordinary skill in the art would recognize many other variations, modifications, and alternatives.

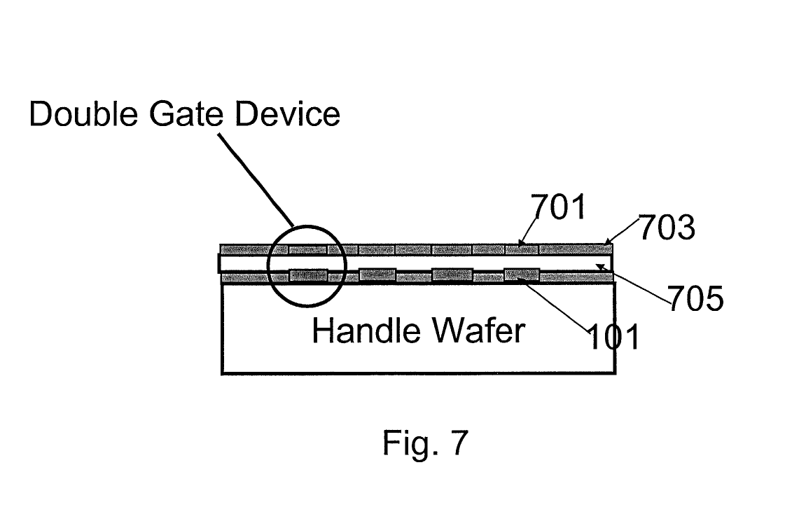

A gate layer 701 is formed overlying the device layer, as shown in FIG. 7. The gate layer can be polysilicon or amorphous silicon, which is crystallized. The gate layer includes a plurality of gate regions, which are defined overlying a gate dielectric layer, e.g., silicon dioxide, silicon nitride, silicon oxynitride. Each of the gate regions is formed using a deposition of polysilicon, which is later patterned to form such regions. The polysilicon is often doped with an impurity. The impurity is often introduced into the polysilicon layer using implantation, diffusion, in-situ doping, any combination of these, and the like. Each of the gate regions 701 opposes a respective gate region 101. A channel region 705 is defined between lower gate region 101 and upper gate region 701 to form a double gate MOS device structure.

The method forms a layer of dielectric material 703 overlying the substrate structure. In a specific embodiment, the method forms a dielectric layer overlying the surface of the substrate structure. The dielectric layer is planarized using chemical mechanical polishing or the like. Alternatively, the dielectric layer can be a spin on glass or other form of material, which fills in the regions or gaps between the gate regions. The substrate structure including gate and dielectric regions has a substantially planar surface in a preferred embodiment.

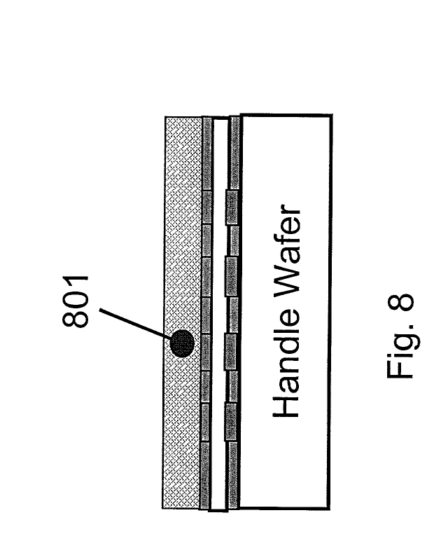

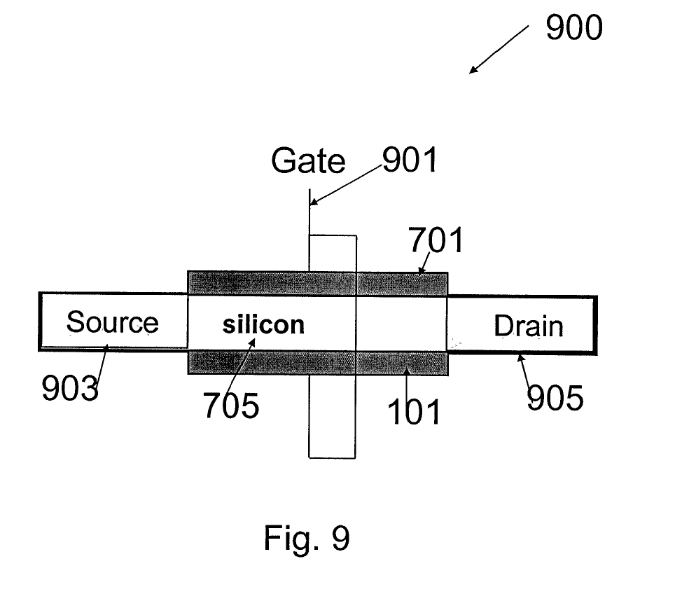

Next, other processing steps can be performed on the double gate semiconductor structure, as shown in FIG. 8. Here, a metal layer can be deposited overlying the gate structure. The top/bottom gates can either be connected together (common gate) as a common gate or be separately configured. In the common gate connection, a deep via structure would be formed to connect both gates together. In the separately connected gate, all bottom gates can either be connected together or separately through the appropriate use of a lithography and etching process, followed by a connection to the bottom electrode. The top gate could be connected through a shallow via connection. A representation of a double gate MOS device structure 900 is shown in FIG. 9. The double gate structure includes upper gate 701 and lower gate 101, where channel region 705 is defined in between such gates. The upper and lower gates are connected to each other through line 901. A source region 903 and a drain region 905 are also defined on the substrate structure.

In operation, a threshold voltage is applied to line 901, which causes a channel region to form between each of the gate regions, including the upper gate region and lower gate region. Once the channel region is formed, the source and drain region are connected to each other. Depending upon the embodiment, the double gate transistor can be operated in enhancement mode or depletion mode. Of course, one of ordinary skill in the art would recognize many other variations, modifications, and alternatives.

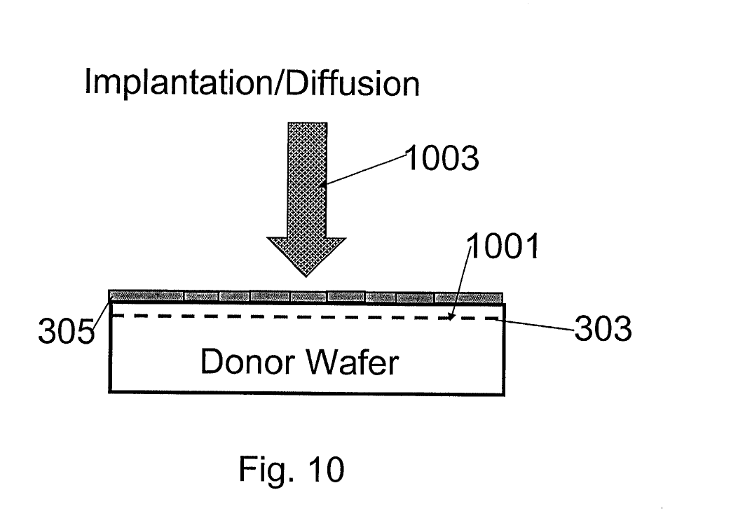

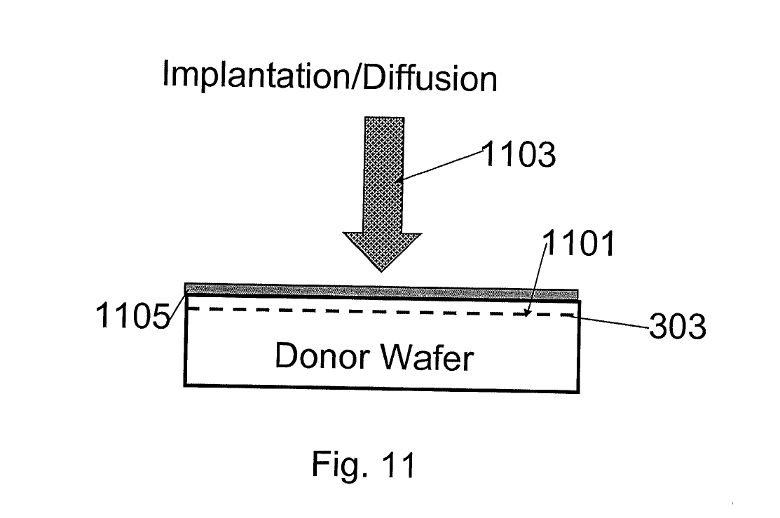

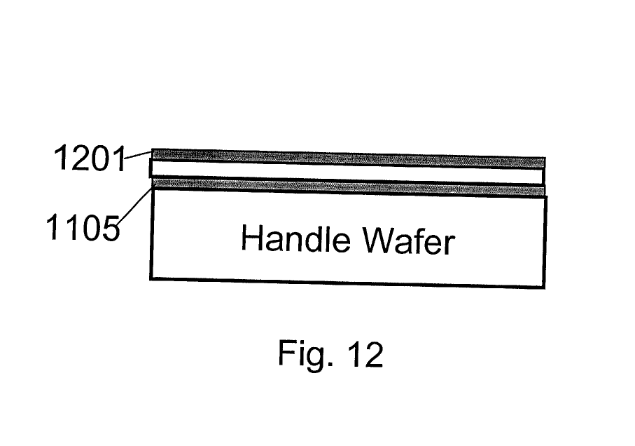

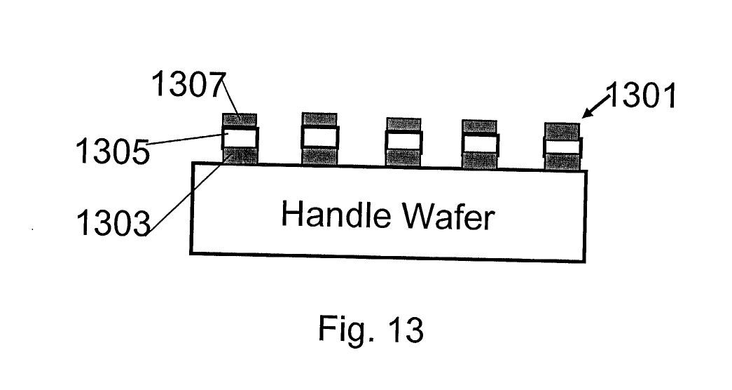

In an alternative embodiment, the donor wafer including gate regions can be made using other techniques, as shown in FIG. 10. Here, we can form a stressed layer or cleaving layer 1001 using alternative methods. The stressed layer can be formed using chemical vapor deposition, physical vapor deposition, molecular beam epitaxy (“MBE”), plating, and other techniques, which include any combination of these. The stressed layer is preferably a silicon alloy, such as silicon germanium or silicon germanium carbon. The silicon germanium carbon layer has a stoichiometry of SiₓGe_{y}, C_{z} where x, y, and z are selectively adjusted during deposition. Adjustment can occur by changing flow rates of respective mass flow controllers. The ratio of silicon to germanium to carbon is selectively adjusted to provide a desired cleaving action according to the present invention. The stressed layer can also be an epitaxial silicon layer. The epitaxial silicon layer is made using an epitaxial reactor. An example of such a reactor is an epi-Centura™ reactor made by Applied Materials, Inc. of Santa Clara, Calif. Other reactors such as those made by ASM and other companies can also be used. Other materials can also be used. Optionally, the stressed layer is a multiple layered structure according to an embodiment of the present invention. The multiple or multilayered structure can include a combination of compressional layers and tensile layers. The present multiple layered structure can be formed by distinct layers or graded layers, depending upon the application. In other embodiments, one or each of these layers can also be doped using in-situ deposition techniques and/or implantation techniques, as will be discussed below. Here, particles are implanted into the stressed layer. Implantation can include introducing particles or impurities such as hydrogen, helium, nitrogen, boron, and other species, which selectively provides a tensile or compressive characteristic to the layer. Other techniques such as in-situ doping and/or diffusion of impurities can also be used to introduce impurities into any one of the layers.

Overlying the stressed layer is the thickness of material layer 305, which can be formed by a variety of techniques. In a specific embodiment, the material layer is a layer where the gates are formed thereon. The material layer is a high quality layer of silicon for example. The material layer can be deposited using chemical vapor deposition, MBE, physical vapor deposition, plating, and other techniques, which include any combination of these. In a preferred embodiment, the material layer is a crystalline silicon layer or epitaxial silicon layer. The epitaxial silicon layer is made by depositing epitaxial silicon that may be doped using one or more dopants. These dopants include among others, boron, phosphorous, arsenic, and oxygen or any combination thereof.

In some embodiments, particles 1003 are introduced through upper surface into the stressed layer Here, particles are implanted through the surface including gate regions to the stressed layer to form a combination of stressed and implanted layer. Depending upon the application, smaller mass particles are generally selected to reduce a possibility of damage to the material region such as those particles noted above. The stressed region preferably cleaves along a region away from a maximum implant region according to the present invention. In the following discussion, the material layer is removed or cleaved from the stressed layer using a controlled cleaving action. The material layer can also be formed using an in-situ doping process, which can be homogeneous or graded, depending upon the application. Depending upon the application, many implant distributions may exist. For example, the implant distribution can have a single maximum, where the maximum is symmetrical or offset to one side or the other side. Alternatively, the distribution can be shaped like a pulse. Alternatively, the distribution can be a combination of these or multiple pulses or multiple maxima, depending upon the application. Additionally, the particles can be diffused through the top surface or bottom surface of the substrate.

In an alternative embodiment, the invention provides a method for a self aligned double gate structure, as illustrated by FIGS. 11 through 13. Here, the method forms a continuous gate layer 1105 defined overlying a cleave layer 1101, which has been implanted 1103 or diffused. The continuous layer can be selected from polysilicon, in-situ doped polysilicon, or the like. The cleave layer extends to selected depth 301. A dielectric layer is defined between the continuous layer and the donor substrate material. The dielectric material will be a gate dielectric layer. Depending upon the embodiment, there can be other variations, modifications, and alternatives.

Next the method bonds the continuous layer to handle wafer, as shown in FIG. 12. An other gate dielectric layer is defined overlying the detached layer. A second gate layer 1201 is defined overlying the gate dielectric layer. The method then uses masking and etching techniques to define a plurality of gate structures 1301, as shown in the simplified diagram of FIG. 13. The etching techniques can include a combination of etching techniques to pattern upper gate 1307, channel regions 1305, and lower gate 1303. Such techniques can be combined with deposition techniques as well to form isolation on edges of the gates, while keeping the sides of the channel regions free from isolation. Source and drain regions can then be formed by selective deposition techniques and the like. Depending upon the embodiment, there can be many other variations, modifications, and alternatives.

In a preferred embodiment, the present invention is practiced at temperatures that are lower than those used by pre-existing techniques. In particular, the present invention does not require increasing the entire substrate temperature to initiate and sustain the cleaving action as pre-existing techniques. In some embodiments for silicon wafers and hydrogen implants, substrate temperature does not exceed about 400° C. during the cleaving process. Alternatively, substrate temperature does not exceed about 350° C. during the cleaving process. Alternatively, substrate temperature is kept substantially below implanting temperatures via a thermal sink, e.g., cooling fluid, cryogenic fluid. Accordingly, the present invention reduces a possibility of unnecessary damage from an excessive release of energy from random cleave fronts, which generally improves surface quality of a detached film(s) and/or the substrate(s). Accordingly, the present invention provides resulting films on substrates at higher overall yields and quality.

The above embodiments are described in terms of cleaving a thin film of material from a substrate. The substrate, however, can be disposed on a workpiece such as a stiffener or the like before the controlled cleaving process. The workpiece joins to a top surface or implanted surface of the substrate to provide structural support to the thin film of material during controlled cleaving processes. The workpiece can be joined to the substrate using a variety of bonding or joining techniques, e.g., electrostatics, adhesives, interatomic. Some of these bonding techniques are described herein. The workpiece can be made of a dielectric material (e.g., quartz, glass, sapphire, silicon nitride, silicon dioxide), a conductive material (silicon, silicon carbide, polysilicon, group III/V materials, metal), and plastics (e.g., polyimide-based materials). Of course, the type of workpiece used will depend upon the application.

Alternatively, the substrate having the film to be detached can be temporarily disposed on a transfer substrate such as a stiffener or the like before the controlled cleaving process. The transfer substrate joins to a top surface or implanted surface of the substrate having the film to provide structural support to the thin film of material during controlled cleaving processes. The transfer substrate can be temporarily joined to the substrate having the film using a variety of bonding or joining techniques, e.g., electrostatics, adhesives, interatomic. Some of these bonding techniques are described herein. The transfer substrate can be made of a dielectric material (e.g., quartz, glass, sapphire, silicon nitride, silicon dioxide), a conductive material (silicon, silicon carbide, polysilicon, group III/V materials, metal), and plastics (e.g., polyimide-based materials). Of course, the type of transfer substrate used will depend upon the application. Additionally, the transfer substrate can be used to remove the thin film of material from the cleaved substrate after the controlled cleaving process.

Although the above description is in terms of a silicon wafer, other substrates may also be used. For example, the substrate can be almost any monocrystalline, polycrystalline, or even amorphous type substrate. Additionally, the substrate can be made of III/V materials such as gallium arsenide, gallium nitride (GaN), and others. The multi-layered substrate can also be used according to the present invention. The multi-layered substrate includes a silicon-on-insulator substrate, a variety of sandwiched layers on a semiconductor substrate, and numerous other types of substrates. Additionally, the embodiments above were generally in terms of providing a pulse of energy to initiate a controlled cleaving action. The pulse can be replaced by energy that is scanned across a selected region of the substrate to initiate the controlled cleaving action. Energy can also be scanned across selected regions of the substrate to sustain or maintain the controlled cleaving action. One of ordinary skill in the art would easily recognize a variety of alternatives, modifications, and variations, which can be used according to the present invention.

As will be further described below, the present invention can be applied to many other related fields. In a specific embodiment, the invention can be applied in the manufacture of CMOS SOI structures, opto-electronics (photonics), micro-fluidics, and the like. The invention can also be used with radiation-hardened insulating layers and high resistivity handle wafers for custom RF and space environment applications. The invention can be used for laminated electronics is the development of efficient starting materials for fabrication of dual-gate, fully-depleted CMOS transistors, expected to become the mainstay of advanced IC devices for gate sizes at 65 nm and smaller. An example of such a schematic of a triple-layer laminate of Si and SiO₂ layers for a prototype dual-gate fully-depleted CMOS substrate is also provided.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A process for forming an integrated circuit device structure, said process comprising:
forming a plurality of first gate structures on a thickness of material on a donor substrate, the donor substrate comprising a cleave region underlying the plurality of gate structures, the cleave region comprising a deposited layer, each of the gate structures having a substantially planar upper surface;
joining the donor substrate to a handle substrate where the plurality of gate structures including the planar upper surface face the handle substrate;
separating the thickness of material at the cleave region from the donor substrate to define a handle substrate comprising the plurality of gate structures and the overlying thickness of material; and
forming a plurality of second gate structures on the thickness of material, at least one of the first gate structures facing one of the second gate structures to form a channel region therebetween.

2. The process of claim 1 wherein the deposited layer comprises silicon germanium.

3. The process of claim 2 wherein the deposited layer further comprises an epitaxial layer.

4. The process of claim 1 wherein the cleave region is derived from layer formed by physical vapor deposition or chemical vapor deposition.

5. The process of claim 1 wherein the separating step is provided by a controlled cleaving action to remove the thickness of material from the donor substrate.

6. The process of claim 1 wherein the donor substrate is a silicon wafer.

7. The process of claim 1 wherein the cleave region further comprises an implanted region comprising hydrogen bearing particles.

8. The process of claim 1 wherein the donor substrate is made of a material selected from the group consisting of silicon, diamond, quartz, glass, sapphire, silicon carbide, dielectric, group III/V material, plastic, ceramic material, and multilayered substrate.

9. The process of claim 1 wherein the donor substrate is planar.

10. The process of claim 1 wherein the donor substrate is curved.

11. A multi-gate MOS transistor structure comprising:
a handle substrate;
a gate region defined overlying the handle substrate;
a first gate dielectric region defined overlying the gate region;
a cleaved region forming a channel region defined overlying the first gate dielectric region and defined overlying the first gate region, the cleaved region having a thickness of less than 250 nm and having a uniformity of 1-10%;
a second gate dielectric region defined overlying the channel region;
a second gate region defined overlying the second gate dielectric region and defined overlying the channel region, whereupon the second gate opposes the first gate and has the channel region defined between the first gate and the second gate.

12. The transistor structure of claim 11 wherein the cleaved region is provided by a controlled cleaving process.

13. A process for forming an integrated circuit device structure, said process comprising:
forming a first gate layer on a thickness of material on a donor substrate, the donor substrate comprising a cleave region underlying the first gate layer, the first gate layer having a substantially planar upper surface;
joining the donor substrate to a handle substrate where the first gate layer including the planar upper surface face the handle substrate;
separating the thickness of material at the cleave region from the donor substrate to define a handle substrate comprising the first gate layer and the overlying thickness of material;
forming a second gate layer overlying the thickness of material to define a sandwiched structure including the first gate layer, the detached thickness of material, and second gate layer; and
patterning the sandwiched structure to define a first gate structure from the first gate layer defined opposite of a second gate structure from the second gate layer using at least an etching process where upon a channel region is defined from the detached and patterned thickness of material defined between the first gate structure and the second gate structure.

14. The method of claim 13 wherein the etching process comprises an anisotropic etching process.

15. The method of claim 13 wherein the first gate structure and second gate structure define a double gated MOS transistor.

16. The method of claim 13 wherein the channel region has a length of less than 100 nm.

17. The method of claim 13 wherein the channel region has a length ranging from about 25 nm to about 100 nm.

18. The method of claim 13 wherein the patterning self aligns the first gate structure with the second gate structure.

19. The method of claim 13 further comprising connecting the first gate structure with the second gate structure through a via structure.

20. The method of claim 13 further comprising connecting the first gate structure to another gate structure.
